(19) United States
(12) Patent Application Publication
(10) Pub. No.: US 2025/0351272 A1
(43) Pub. Date: Nov. 13, 2025

(54) SUBSTRATE STRUCTURE

(71) Applicant: Unimicron Technology Corp., Taoyuan City (TW)

(72) Inventors: Chin-Sheng Wang, Taoyuan City (TW); Ra-Min Tain, Hsinchu County (TW)

(73) Assignee: Unimicron Technology Corp., Taoyuan City (TW)

(21) Appl. No.: 19/227,419

(22) Filed: Jun. 3, 2025

Related U.S. Application Data
(63) Continuation-in-part of application No. 19/174,951, filed on Apr. 10, 2025.
Application No. 19/174,951 is a continuation-in-part of application No. 18/668,275, filed on May 20, 2024.
(60) Provisional application No. 63/643,932, filed on May 8, 2024.
(60) Provisional application No. 63/658,882, filed on Jun. 12, 2024.
(60) Provisional application No. 63/668,751, filed on Jul. 8, 2024.

(30) Foreign Application Priority Data
Dec. 31, 2024 (TW) 113151809
May 6, 2025 (TW) 114116904

(51) Int. Cl. H05K 1/14; H05K 1/03; H05K 1/11

(52) U.S. Cl. CPC H05K 1/144; H05K 1/0306; H05K 1/0313; H05K 1/112; H05K 2201/0344; H05K 2201/042; H05K 2201/10287; H05K 2201/10318

(57) ABSTRACT

A substrate structure includes a first substrate, a second substrate, a third substrate, and an electroless metal material. The first substrate includes at least one first consecutive via, at least one first pad, at least one second pad, multiple first nano-metal wires, and multiple second nano-metal wires. The second substrate includes at least one third pad, multiple third nano-metal wires, and at least one second conductive via. The third substrate includes at least one fourth pad, multiple fourth nano-metal wires, and at least one third conductive via. The at least one first pad is electrically connected to the at least one third pad through the electroless metal material. The at least one second pad is electrically connected to the at least one fourth pad through the electroless metal material.

### CROSS-REFERENCE TO RELATED APPLICATION

This application is a continuation-in-part application of and claims the priority benefit of U.S. application Ser. No. 19/174,951, filed on Apr. 10, 2025, which is a continuation-in-part application of and claims the priority benefit of U.S. application Ser. No. 18/668,275, filed on May 20, 2024, and also claims the priority benefits of U.S. Provisional Application No. 63/643,932, filed on May 8, 2024, U.S. Provisional Application No. 63/658,882, filed on Jun. 12, 2024, and Taiwan application serial no. 113151809, filed on Dec. 31, 2024. This application also claims the priority benefits of U.S. provisional application Ser. No. 63/668,751, filed on Jul. 8, 2024, and Taiwan application serial no. 114116904, filed on May 6, 2025. The entirety of each of the above-mentioned patent applications is hereby incorporated by reference herein and made a part of this specification.

### BACKGROUND

### Technical Field

The disclosure relates to a substrate structure, and more particularly to a substrate structure having a conductive via with a high aspect ratio.

### Description of Related Art

Currently, in order to manufacture a through glass via (TGV) with a high aspect ratio (AR) in a glass substrate, the glass substrates are usually bonded through a resin material, and the through glass vias in the two glass substrates are electrically connected through a conductive paste in the resin material. In other words, after the two glass substrates are bonded, there is the conductive paste between the through glass vias. Alternatively, the thickness of the adopted glass substrate is greater than 200 μm, such as 500 μm, and the through glass via with the high aspect ratio is formed through procedures such as laser, etching, and hole filling. As such, it can be known that it is difficult to manufacture through glass vias with high aspect ratios in glass substrates.

### SUMMARY

The disclosure provides a substrate structure with improved structural reliability.

A substrate structure of the disclosure includes a first substrate, a second substrate, a third substrate, and an electroless metal material. The first substrate has a first surface and a second surface opposite to each other and includes at least one first conductive via, at least one first pad, at least one second pad, multiple first nano-metal wires, and multiple second nano-metal wires. The at least one first pad and the at least one second pad are respectively located on the first surface and the second surface and are connected to the at least one first conductive via. The first nano-metal wires are disposed on the at least one first pad, and the second nano-metal wires are disposed on the at least one second pad. The second substrate is disposed on the first surface of the first substrate and includes at least one third pad facing the first surface, multiple third nano-metal wires disposed on the at least one third pad, and at least one second conductive via connected to the at least one third pad. The third substrate is disposed on the second surface of the first substrate and includes at least one fourth pad facing the second surface, multiple fourth nano-metal wires disposed on the at least one fourth pad, and at least one third conductive via connected to the at least one fourth pad. The electroless metal material directly covers the at least one first pad, the first nano-metal wires, the at least one third pad, the third nano-metal wires, the at least one second pad, the second nano-metal wires, the at least one fourth pad, and the fourth nano-metal wires. The at least one first pad is electrically connected to the at least one third pad through the electroless metal material. The at least one second pad is electrically connected to the at least one fourth pad through the electroless metal material.

In an embodiment of the disclosure, the substrate structure further includes an underfill filled between the first surface of the first substrate and the second substrate and between the second surface of the first substrate and the third substrate, and covering the electroless metal material.

In an embodiment of the disclosure, the first substrate includes an organic base. A material of the organic base includes a glass fiber resin, a prepreg, or polyimide.

In an embodiment of the disclosure, the second substrate and the third substrate respectively have an inorganic base. A material of the inorganic base includes glass, ceramic, or glass ceramic.

In an embodiment of the disclosure, the electroless metal material includes electroless copper plating, electroless gold plating, or electroless nickel plating.

In an embodiment of the disclosure, the second substrate further includes at least one first wiring pattern facing the first surface. The third substrate further includes at least one second wiring pattern facing the second surface. The electroless metal material further covers a peripheral surface of the at least one first wiring pattern and a peripheral surface of the at least one second wiring pattern.

In an embodiment of the disclosure, the electroless metal material exposes a part of the first surface and a part of the second surface of the first substrate, a part of a third surface of the second substrate facing the first surface, and a part of a fourth surface of the third substrate facing the second surface.

In an embodiment of the disclosure, the at least one first conductive via and the at least one second conductive via are located on a same axis.

In an embodiment of the disclosure, the at least one first conductive via and the at least one third conductive via are located on a same axis.

In an embodiment of the disclosure, respectively between the first nano-metal wires and the third nano-metal wires and between the second nano-metal wires and the fourth nano-metal wires, one of following conditions is satisfied: (1) complete direct contact; (2) partial direct contact; and (3) no contact.

In an embodiment of the disclosure, a length of each of the first nano-metal wires, a length of each of the second nano-metal wires, a length of each of the third nano-metal wires, and a length of each of the fourth nano-metal wires are between 1 μm and 50 μm.

Based on the above, in the substrate structure of the disclosure, the electroless metal material directly covers the first pad and the first nano-metal wire thereon and the third pad and the third nano-metal wire thereon, and directly covers the second pad and the second nano-metal wire thereon and the fourth pad and the fourth nano-metal wire thereon. The first pad is electrically connected to the third pad through the electroless metal material, and the second pad is electrically connected to the fourth pad through the electroless metal material. That is, the first pad and the third pad and the second pad and the fourth pad may be bonded through metal-to-metal diffusion between the nano-metal wires, and the gaps between the nano-metal wires may also be filled through the electroless metal material, so as to increase bonding yields between the first pad and the third pad and between the second pad and the fourth pad, so that the substrate structure has improved structural reliability. In addition, through bonding the first substrate, the second substrate, and the third substrate in the above manner, the substrate structure having a conductive via with a high aspect ratio may be formed.

In order for the features and advantages of the disclosure to be more comprehensible, the following specific embodiments are described in detail in conjunction with the drawings.

### BRIEF DESCRIPTION OF THE DRAWINGS

FIG. 1A to FIG. 1N are schematic views of a manufacturing method of a substrate structure according to an embodiment of the disclosure.

### DESCRIPTION OF THE EMBODIMENTS

The embodiments of the disclosure may be understood in conjunction with the drawings, and the drawings of the disclosure are also considered as a part of the disclosure. It should be understood that the drawings of the disclosure are not drawn to scale, and in fact the sizes of elements may be arbitrarily enlarged or reduced in order to clearly illustrate the features of the disclosure.

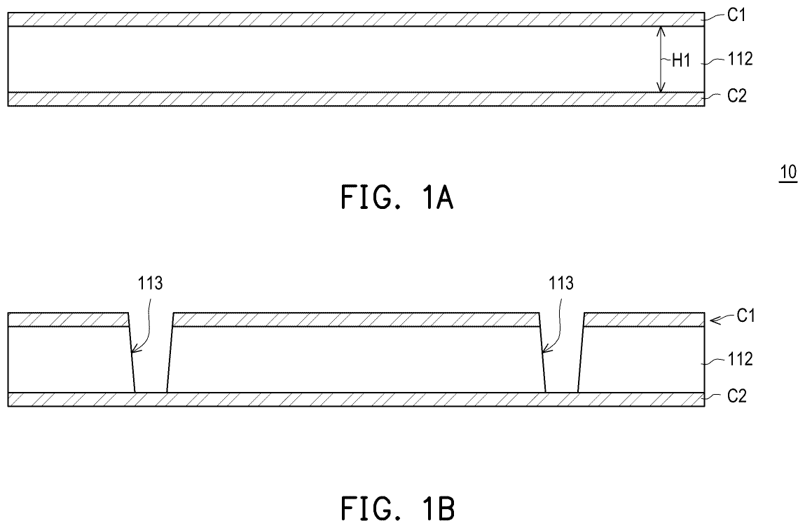

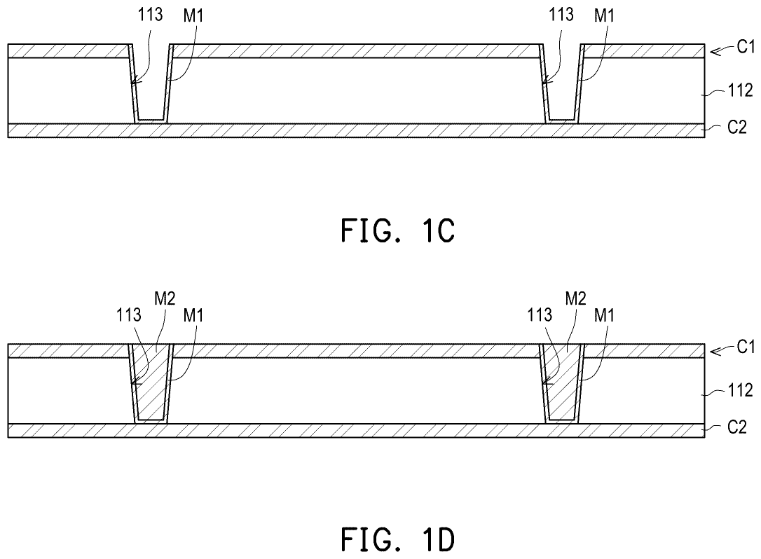

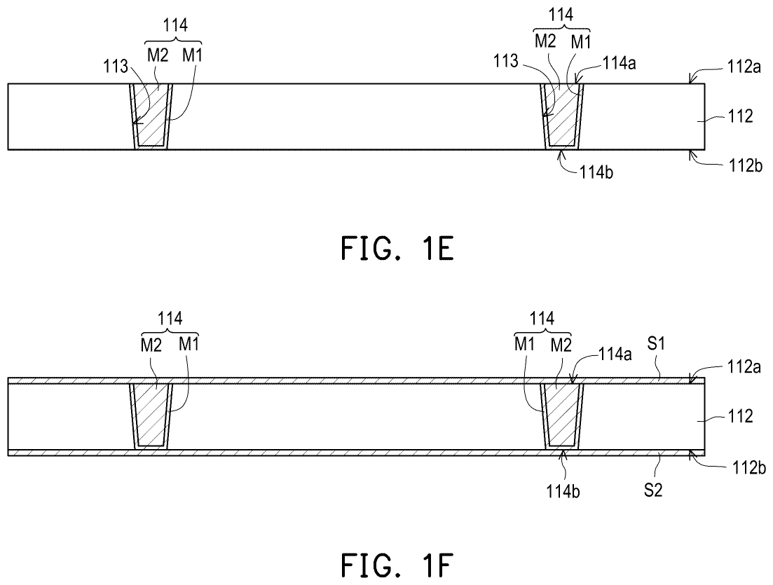

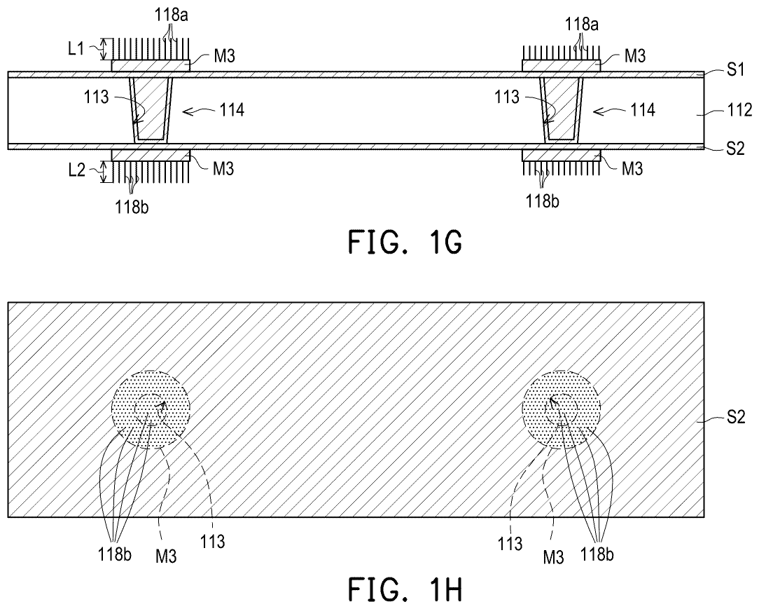

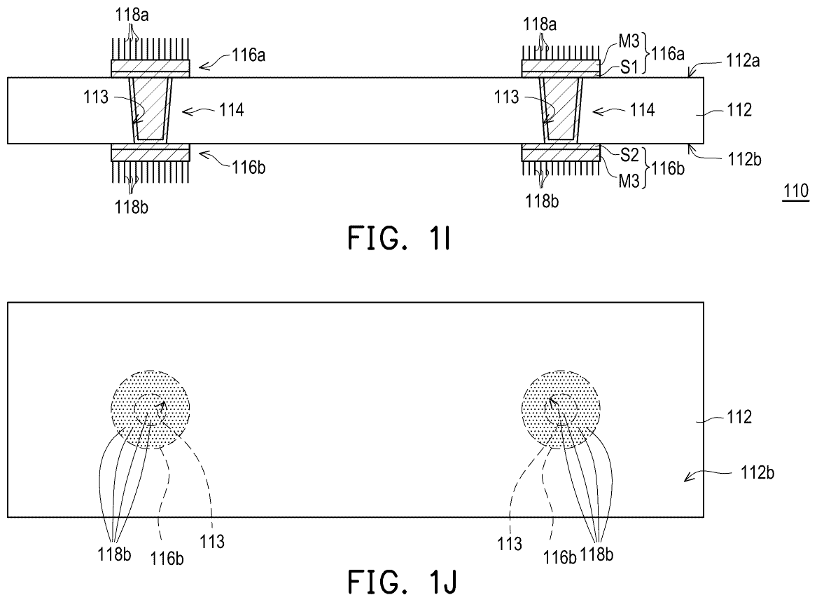

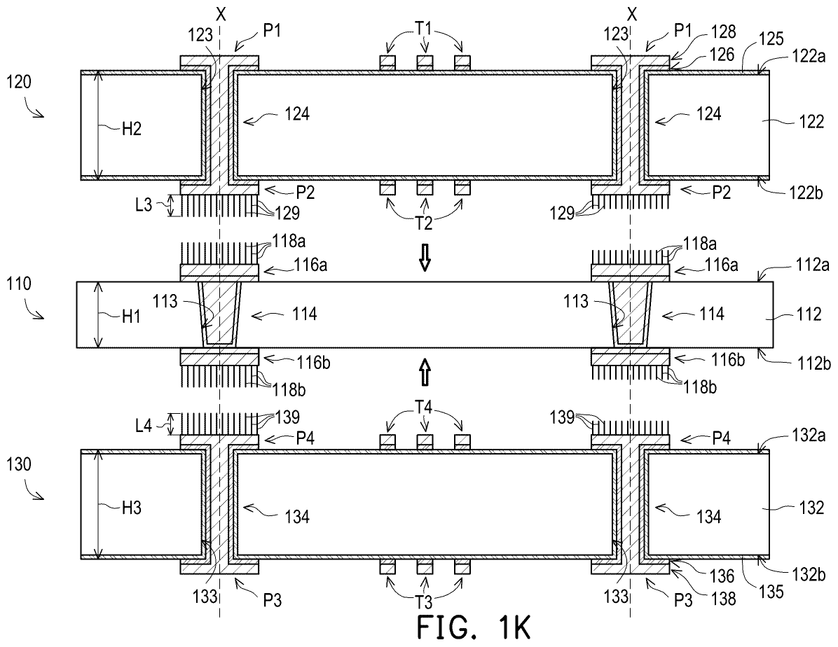

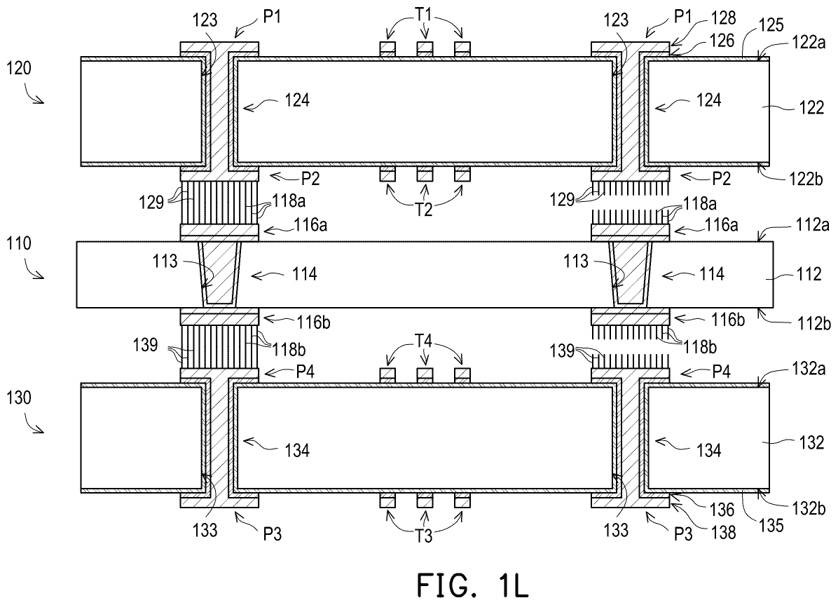

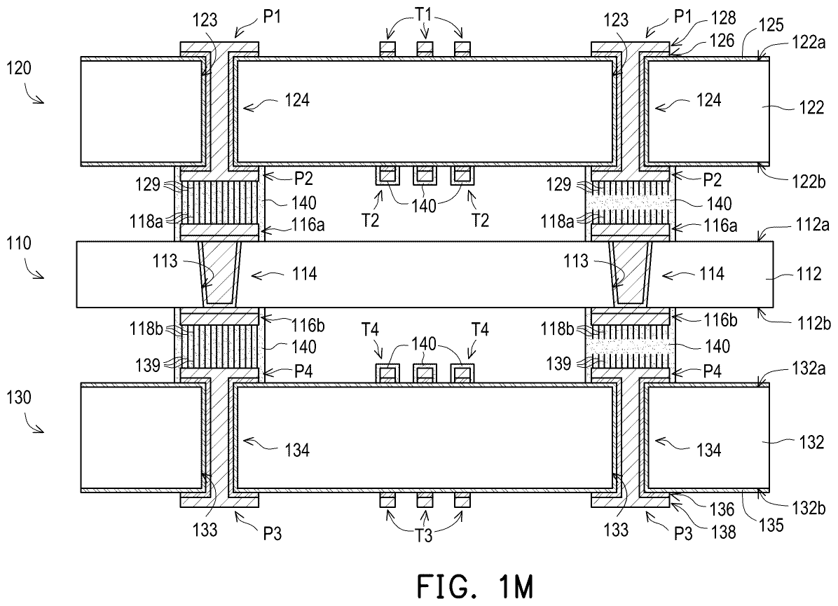

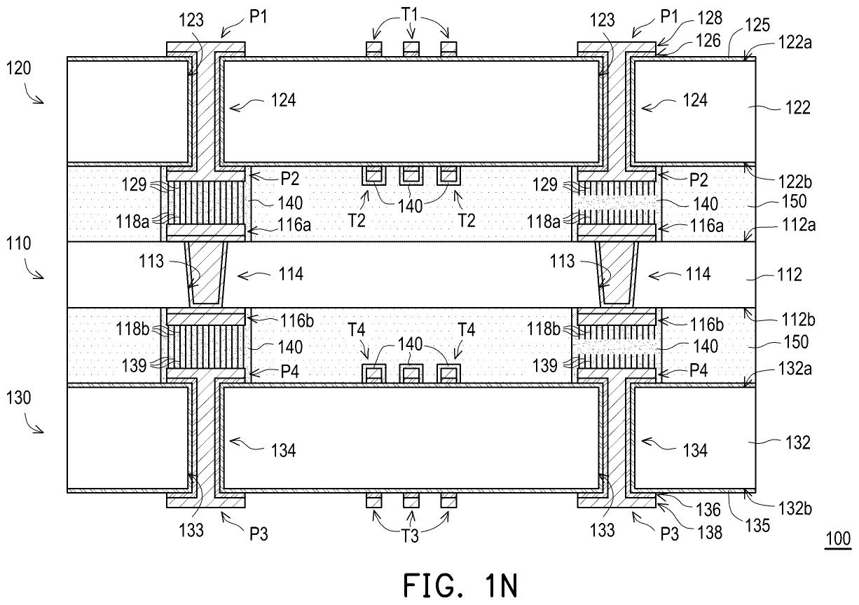

FIG. 1A to FIG. 1N are schematic views of a manufacturing method of a substrate structure according to an embodiment of the disclosure. It should be noted that FIG. 1A to FIG. 1G, FIG. 1I, and FIG. 1K to FIG. 1N are cross-sectional schematic views, FIG. 1H is a bottom schematic view of FIG. 1G, and FIG. 1J is a bottom schematic view of FIG. 1I.

According to the manufacturing method of the substrate structure of the embodiment, firstly, please refer to FIG. 1A first. An initial substrate 10 is provided. The initial substrate 10 includes an organic base 112 and metal layers C1 and C2 disposed on two opposite surfaces of the organic base 112, wherein the metal layers C1 and C2 completely cover the surface of the organic base 112. In an embodiment, the material of the organic base 112 includes a glass fiber resin, a prepreg (PP), or polyimide (PI). In an embodiment, the material of the organic base 112 is the glass fiber resin, the metal layers C1 and C2 are copper foil layers, and the initial substrate 10 is a copper clad laminate (CCL). In an embodiment, the initial substrate 10 is a flexible copper clad laminate (FCCL). In an embodiment, when the material of the organic base 112 is the prepreg (PP), a thickness H1 thereof is 20 μm to 100 μm. In an embodiment, when the material of the organic base 112 is polyimide (PI), the thickness H1 thereof is 10 μm to 60 μm.

Next, please refer to FIG. 1A and FIG. 1B at the same time. An opening 113 is formed on the initial substrate 10 by laser ablation or mechanical drilling. The opening 113 extends from the metal layer C1 through the organic base 112 to the metal layer C2, wherein the opening 113 does not penetrate the metal layer C2. In an embodiment, the diameter of the opening 113 gradually increases in a direction from the metal layer C2 toward the metal layer C1, but not limited thereto.

Next, please refer to FIG. 1C. A metallization layer M1 is formed on the inner wall of the opening 113 by a sputtering procedure or an electroless procedure. The metallization layer M1 directly contacts the inner wall of the opening 113 and a part of the metal layer C2.

Next, please refer to FIG. 1D. A metal material M2 is formed in the opening 113 by electroplating and completely fills the opening 113, wherein the metallization layer M1 is located between the metal material M2 and the opening 113. In an embodiment, the metal material M2 is, for example, copper.

Next, please refer to FIG. 1D and FIG. 1E at the same time. The metal layer C1, the metal layer C2, a part of the metallization layer M1, and a part of the metal material M2 are removed by etching or chemical mechanical polishing (CMP) to form a first conductive via 114 penetrating the organic base 112. The first conductive via 114 includes the metallization layer M1 and the metal material M2. The organic base 112 has a first surface 112a and a second surface 112b opposite to each other. The first conductive via 114 has a first end 114a and a second end 114b opposite to each other, wherein the first end 114a is flush with the first surface 112a, and the second end 114b is flush with the second surface 114b.

Next, please refer to FIG. 1F. A seed layer S1 is formed on the first surface 112a of the organic base 112, and a seed layer S2 is formed on the second surface 112b of the organic base 112. The seed layer S1 directly covers the first surface 112a of the organic base 112 and the first end 114a of the first conductive via 114. The seed layer S2 directly covers the second surface 112b of the organic base 112 and the second end 114b of the first conductive via 114. In an embodiment, the material of the seed layer S1 and the material of the seed layer S2 are, for example, electroless copper or sputtered titanium/copper.

Next, please refer to FIG. 1G and FIG. 1H at the same time. A patterned conductive layer M3 is formed on the seed layer S1 and the seed layer S2 by electroplating. The orthographic projection of the patterned conductive layer M3 on the organic base 112 completely overlaps with the first conductive via 114. Next, multiple first nano-metal wires 118a are formed on the patterned conductive layer M3 on the seed layer S1 by electroplating, and multiple second nano-metal wires 118b are formed on the patterned conductive layer M3 on the seed layer S2.

The first nano-metal wire 118a and the second nano-metal wire 118b respectively extend toward a direction away from the organic base 112. In an embodiment, when viewed from below, the shape of the patterned conductive layer M3 is circular, so the distribution of the second nano-metal wires 118b is circular, but not limited thereto. In an embodiment, the distribution shapes of the first nano-metal wires 118a and the second nano-metal wires 118b may be changed along with the shape of the patterned conductive layer M3.

In an embodiment, the first nano-metal wires 118a are separated from each other, and a length L1 of the first nano-metal wire 118a is, for example, between 1 μm and 50 μm. In an embodiment, the first nano-metal wires 118a may have the same length L1. In an embodiment, the first nano-metal wires 118a may have different lengths L1. In an embodiment, the second nano-metal wires 118b are separated from each other, and a length L2 of the second nano-metal wire 118b is, for example, between 1 μm and 50 μm. In an embodiment, the second nano-metal wires 118b may have the same length L2. In an embodiment, the second nano-metal wires 118b may have different lengths L2. In an embodiment, the diameter of the first nano-metal wire 118a and the diameter of the second nano-metal wire 118b may be respectively, for example, between 4 nm and 4 μm.

Next, please refer to FIG. 1G, FIG. 1H, FIG. 1I, and FIG. 1J at the same time. The seed layer S1 and the seed layer S2 exposed outside the patterned conductive layer M3 are removed to define a first pad 116a on the first surface 112a of the organic base 112 and a second pad 116b on the second surface 112b of the organic base 112. The first pad 116a includes the seed layer S1 and the patterned conductive layer M3. The second pad 116b includes the seed layer S2 and the patterned conductive layer M3. So far, the manufacturing of the first substrate 110 is completed.

Next, please refer to FIG. 1K, a second substrate 120 is provided on the first surface 112a of the first substrate 110. The second substrate 120 includes an inorganic base 122, an adhesion promoting layer 125, a metal layer 126, a conductive material 128, and a third nano-metal wire 129. The inorganic base 122 has an upper surface 122a and a lower surface 122b opposite to each other and a via 123 penetrating the inorganic base 122 and connecting the upper surface 122a and the lower surface 122b. In an embodiment, a thickness H2 of the inorganic base 122 is between 50 μm and 1000 μm. The adhesion promoting layer 125 is disposed on the upper surface 122a, the lower surface 122b, and the inner wall of the via 123 of the inorganic base 122. It should be noted that the second substrate 120 is a substrate produced after a singulation cutting procedure. Therefore, after cutting, the peripheral surface of the inorganic base 122 is not covered by the adhesion promoting layer 125. The metal layer 126 is disposed on a part of the adhesion promoting layer 125, which means that the metal layer 126 does not completely cover the adhesion promoting layer 125, but exposes another part of the adhesion promoting layer 125.

The conductive material 128 is disposed on the metal layer 126 and fills the via 123 to define a pad P1 located on the upper surface 122a, a third pad P2 located on the lower surface 122b, a second conductive via 124 located in the via 123 and electrically connecting the pad P1 and the third pad P2, and wiring patterns T1 and T2 located on the adhesion promoting layer 125. The third nano-metal wire 129 is disposed on the third pad P2 and extends toward the first nano-metal wire 118a.

In an embodiment, the third nano-metal wires 129 are separated from each other, and a length L3 of the third nano-metal wire 129 is, for example, between 1 μm and 50 μm. In an embodiment, the third nano-metal wires 129 may have the same length L3. In an embodiment, the third nano-metal wires 129 may have different lengths L3. In an embodiment, the diameter of the third nano-metal wire 129 may be, for example, between 4 nm and 4 μm. In an embodiment, the material of the inorganic base 122 is, for example, glass, ceramic, or glass ceramic. In an embodiment, the material of the adhesion promoting layer 125 is, for example, an oxide or a nitride, wherein the oxide is, for example, TiO_{X} (for example, TiO or TiO₂), SiO_{X} (for example, SiO₂), or Al₂O₃, and the nitride is, for example, SiN_{X} (for example, Si₃N₄). In the embodiment, the thickness of the adhesion promoting layer 125 is, for example, between 0.01 nm and 100 nm, wherein the adhesion promoting layer 125 may increase adhesion between the inorganic base 122 and the metal layer 126. In an embodiment, the adhesion promoting layer 125 may be selectively provided, which means that the adhesion promoting layer 125 may also be omitted.

Next, a third substrate 130 is provided on the second surface 112b of the first substrate 110, wherein the third substrate 130 and the second substrate 120 may have the same or similar structural configurations. In detail, the third substrate 130 includes an inorganic base 132, an adhesion promoting layer 135, a metal layer 136, a conductive material 138, and a fourth nano-metal wire 139. The inorganic base 132 has an upper surface 132a and a lower surface 132b opposite to each other and a via 133 penetrating the inorganic base 132 and connecting the upper surface 132a and the lower surface 132b. In an embodiment, a thickness H3 of the inorganic base 132 is between 50 μm and 1000 μm. The adhesion promoting layer 135 is disposed on the upper surface 132a, the lower surface 132b, and the inner wall of the via 133 of the inorganic base 132. It should be noted that the third substrate 130 is a substrate produced after a singulation cutting procedure. Therefore, after cutting, the peripheral surface of the inorganic base 132 is not covered by the adhesion promoting layer 135. The metal layer 136 is disposed on a part of the adhesion promoting layer 135, which means that the metal layer 136 does not completely cover the adhesion promoting layer 135, but exposes another part of the adhesion promoting layer 135. The conductive material 138 is disposed on the metal layer 136 and fills the via 133 to define a fourth pad P4 located on the upper surface 132a, a pad P3 located on the lower surface 132b, a third conductive via 134 located in the via 133 and electrically connecting the fourth pad P4 and the pad P3, and wiring patterns T3 and T4 located on the adhesion promoting layer 135. The fourth nano-metal wire 139 is disposed on the fourth pad P4 and extends toward the second nano-metal wire 118b. In an embodiment, the adhesion promoting layer 135 may be selectively provided, which means that the adhesion promoting layer 135 may also be omitted.

In an embodiment, the fourth nano-metal wires 139 are separated from each other, and a length L4 of the fourth nano-metal wire 139 is, for example, between 1 μm and 50 μm. In an embodiment, the fourth nano-metal wires 139 may have the same length L4. In an embodiment, the fourth nano-metal wires 139 may have different lengths L4. In an embodiment, the diameter of the fourth nano-metal wire 139 may be, for example, between 4 nm and 4 μm. In an embodiment, the material of the inorganic base 132 is, for example, glass, ceramic, or glass ceramic. In an embodiment, the adhesion promoting layer 135 may be selectively provided. In an embodiment, the material of the adhesion promoting layer 135 is, for example, an oxide or a nitride, wherein the oxide is, for example, TiO_{X} (for example, TiO or TiO₂), SiO_{X} (for example, SiO₂), or Al₂O₃, and the nitride is, for example, SiN_{X} (for example, Si₃N₄). In the embodiment, the thickness of the adhesion promoting layer 135 is, for example, between 0.01 nm and 100 nm, wherein the adhesion promoting layer 135 may increase adhesion between the inorganic base 132 and the metal layer 136. In an embodiment, the thickness H1 of the organic base 112 of the first substrate 110 is less than the thickness H2 of the inorganic base 122 of the second substrate 120 and the thickness H3 of the inorganic base 132 of the third substrate 130. In an embodiment, the first conductive via 114 and the second conductive via 124 are located on the same axis X. In an embodiment, the first conductive via 114 and the third conductive via 134 are located on the same axis X.

Next, please refer to FIG. 1K and FIG. 1L at the same time. The second substrate 120, the first substrate 110, and the third substrate 130 are pressed together through heating and pressurizing. During the pressing process, the third nano-metal wire 129 located on the third pad P2 may directly contact, partially contact, or not contact the first nano-metal wire 118a located on the first pad 116a, and the fourth nano-metal wire 139 located on the fourth pad P4 may directly contact, partially contact, or not contact the second nano-metal wire 118b located on the second pad 116b. In an embodiment, “contact” may include point contact or surface contact between the nano-metal wires on two sides. Alternatively, the nano-metal wires on two sides may be deformed due to transitional contact caused by pressure, resulting in the orthographic projections of the deformed nano-metal wires on the substrate being greater than the orthographic projections of the pads on the substrate. In an embodiment, “not contact” includes having an air gap between the nano-metal wires on two sides or the nano-metal wires on two sides being in an interlaced (for example, fence-shaped) state.

When the third nano-metal wire 129 located on the third pad P2 contacts the first nano-metal wire 118a located on the first pad 116a, the third nano-metal wire 129 and the first nano-metal wire 118a are bonded together through metal-to-metal diffusion, so that the second conductive via 124 of the second substrate 120 is electrically connected to the first conductive via 114 of the first substrate 110. When the fourth nano-metal wire 139 located on the fourth pad P4 contacts the second nano-metal wire 118b located on the second pad 116b, the fourth nano-metal wire 139 and the second nano-metal wire 118b are bonded together through metal-metal diffusion, so that the third conductive via 134 of the third substrate 130 is electrically connected to the first conductive via 114 of the first substrate 110.

Next, please refer to FIG. 1M. An electroless procedure is performed to form an electroless metal material 140 to directly cover the peripheral surfaces of the first pad 116a, the first nano-metal wire 118a, the third pad P2, the third nano-metal wire 129, the second pad 116b, the second nano-metal wire 118b, the fourth pad P4, the fourth nano-metal wire 139, and the wiring patterns T2 and T4. The electroless metal material 140 directly covers the peripheral surface of the first pad 116a, the peripheral surface of the third pad P2, the first nano-metal wire 118a located on the first pad 116a, and the third nano-metal wire 129 located on the third pad P2 and fills a gap between the first nano-metal wire 118a and the third nano-metal wire 129, so that the first pad 116a may be electrically connected to the third pad P2 through the electroless metal material 140. In other words, when the first pad 116a and the third pad P2 are electrically conducted through the first nano-metal wire 118a and the third nano-metal wire 129 contacting each other, the electroless metal material 140 may further enhance electrical conduction. When the first nano-metal wire 118a and the third nano-metal wire 129 do not contact and the first pad 116a and the third pad P2 are not electrically connected, the setting of the electroless metal material 140 may electrically connect the first nano-metal wire 118a and the third nano-metal wire 129, so that the first pad 116a and the third pad P2 may be electrically connected through the electroless metal material 140. In an embodiment, the orthographic projection area of the electroless metal material 140 on the first substrate 110 is greater than the area of the first pad 116a, and the electroless metal material 140 exposes a part of the first surface 112a and a part of the adhesion promoting layer 125 located on the third surface 122b.

Similarly, the electroless metal material 140 directly covers the peripheral surface of the second pad 116b, the peripheral surface of the fourth pad P4, the second nano-metal wire 118b located on the second pad 116b, and the fourth nano-metal wire 139 located on the fourth pad P4 and fills a gap between the second nano-metal wire 118b and the fourth nano-metal wire 139, so that the second pad 116b may be electrically connected to the fourth pad P4 through the electroless metal material 140. In other words, when the second pad 116b and the fourth pad P4 are electrically connected through the second nano-metal wire 118b and the fourth nano-metal wire 139 contacting each other, the electroless metal material 140 may further enhance electrical conduction. When the second nano-metal wire 118b and the fourth nano-metal wire 139 do not contact and the second pad 116b and the fourth pad P4 are not electrically connected, the electroless metal material 140 may electrically connect the second nano-metal wire 118b and the fourth nano-metal wire 139, so that the second pad 116b and the fourth pad P4 may be electrically connected through the electroless metal material 140. In an embodiment, the orthographic projection area of the electroless metal material 140 on the first substrate 110 is greater than the area of the second pad 116b, and the electroless metal material 140 exposes a part of the second surface 112b and a part of the adhesion promoting layer 135 located on the fourth surface 132a. In addition, the electroless metal material 140 also conformally directly cover the peripheral surfaces of the wiring patterns T2 and T4. In an embodiment, the electroless metal material 140 directly covers a metal component located between the first surface 112a of the first substrate 110 and the third surface 122b of the second substrate 120 and a metal component located between the second surface 112b of the first substrate 110 and the fourth surface 132a of the third substrate 130. At this time, the first conductive via 114 of the first substrate 110 electrically connects the second conductive via 124 of the second substrate 120 and the third conductive via 134 of the third substrate 130 to form a conductive via with a high aspect ratio.

Finally, please refer to FIG. 1N. An underfill 150 is optionally filled between the first surface 112a of the first substrate 110 and the second substrate 120 and between the second surface 112b of the first substrate 110 and the third substrate 130, and covers the electroless metal material 140. The underfill 150 may enhance bonding strengths between the first substrate 110 and the second substrate 120 and between the first substrate 110 and the third substrate 130. In an embodiment, the peripheral surface of the inorganic base 122 of the second substrate 120, the peripheral surface of the underfill 150, the peripheral surface of the organic base 112 of the first substrate 110, and the peripheral surface of the inorganic base 132 of the third substrate 130 are flush with each other. So far, the manufacturing of the substrate structure 100 is completed.

Please refer to FIG. 1N again. Structurally, the substrate structure 100 includes the first substrate 110, the second substrate 120, the third substrate 130, and the electroless metal material 140. The first substrate 110 has the first surface 112a and the second surface 112b opposite to each other and includes the first conductive via 114, the first pad 116a, the second pad 116b, the first nano-metal wire 118a, and the second nano-metal wire 118b. The first pad 116a and the second pad 116b are respectively located on the first surface 112a and the second surface 112b and are connected to the first conductive via 114. The first nano-metal wire 118a is disposed on the first pad 116a, and the second nano-metal wire 118b is disposed on the second pad 116b. The second substrate 120 is disposed on the first surface 112a of the first substrate 110 and includes the third pad P2 facing the first surface 112a, the third nano-metal wire 129 disposed on the third pad P2, and the second conductive via 124 connected to the third pad P2. The third substrate 130 is disposed on the second surface 112b of the first substrate 110 and includes the fourth pad P4 facing the second surface 112b, the fourth nano-metal wire 139 disposed on the fourth pad P4, and the third conductive via 134 connected to the fourth pad P4. The electroless metal material 140 directly covers the first pad 116a, the first nano-metal wire 118a, the third pad P2, the third nano-metal wire 129, the second pad 116b, the second nano-metal wire 118b, the fourth pad P4, and the fourth nano-metal wire 139. The first pad 116a is electrically connected to the third pad P2 through the electroless metal material 140. The second pad 116b is electrically connected to the fourth pad P4 through the electroless metal material 140.

Furthermore, in the embodiment, the second substrate 120 further includes the first wiring pattern T2 facing the first surface 112a. The third substrate 130 further includes the second wiring pattern T4 facing the second surface 112b. The electroless metal material 140 further covers the peripheral surface of the first wiring pattern T2 and the peripheral surface of the second wiring pattern T4. In other words, the electroless metal material 140 exposes a part of the first surface 112a and a part of the second surface 112b of the first substrate 110, a part of the third surface 122b of the second substrate 120 facing the first surface 112a, and a part of the fourth surface 132a of the third substrate 130 facing the second surface 112b. In an embodiment, the electroless metal material 140 is, for example, electroless copper plating, electroless gold plating, or electroless nickel plating.

In addition, the substrate structure 100 of the embodiment may further selectively include the underfill 150 filled between the first surface 112a of the first substrate 110 and the second substrate 120 and between the second surface 112b of the first substrate 110 and the third substrate 130, and covers the electroless metal material 140 to enhance the bonding strengths between the first substrate 110 and the second substrate 120 and between the first substrate 110 and the third substrate 130, and protect a conductive structure covered by the electroless metal material 140.

In summary, in the substrate structure of the disclosure, the electroless metal material directly covers the first pad and the first nano-metal wire thereon and the third pad and the third nano-metal wire thereon, and directly covers the second pad and the second nano-metal wire thereon and the fourth pad and the fourth nano-metal wire thereon, wherein the first pad is electrically connected to the third pad through the electroless metal material, and the second pad is electrically connected to the fourth pad through the electroless metal material. That is, the first pad and the third pad and the second pad and the fourth pad may be bonded through metal-to-metal diffusion between the nano-metal wires, and the gaps between the nano-metal wires may also be filled through the electroless metal material, so as to increase bonding yields between the first pad and the third pad and between the second pad and the fourth pad, so that the substrate structure has improved structural reliability. In addition, through bonding the first substrate, the second substrate, and the third substrate in the above manner, the substrate structure having the conductive via with the high aspect ratio may be formed.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A substrate structure, comprising:
a first substrate, having a first surface and a second surface opposite to each other and comprising at least one first conductive via, at least one first pad, at least one second pad, a plurality of first nano-metal wires, and a plurality of second nano-metal wires, wherein the at least one first pad and the at least one second pad are respectively located on the first surface and the second surface and are connected to the at least one first conductive via, the first nano-metal wires are disposed on the at least one first pad, and the second nano-metal wires are disposed on the at least one second pad;
a second substrate, disposed on the first surface of the first substrate and comprising at least one third pad facing the first surface, a plurality of third nano-metal wires disposed on the at least one third pad, and at least one second conductive via connecting the at least one third pad;
a third substrate, disposed on the second surface of the first substrate and comprising at least one fourth pad facing the second surface, a plurality of fourth nano-metal wires disposed on the at least one fourth pad, and at least one third conductive via connecting the at least one fourth pad; and
an electroless metal material, directly covering the at least one first pad, the first nano-metal wires, the at least one third pad, the third nano-metal wires, the at least one second pad, the second nano-metal wires, the at least one fourth pad, and the fourth nano-metal wires, wherein the at least one first pad is electrically connected to the at least one third pad through the electroless metal material, and the at least one second pad is electrically connected to the at least one fourth pad through the electroless metal material.

2. The substrate structure according to claim 1, further comprising:
an underfill, filled between the first surface of the first substrate and the second substrate and between the second surface of the first substrate and the third substrate, and covering the electroless metal material.

3. The substrate structure according to claim 1, wherein the first substrate has an organic base, and a material of the organic base comprises a glass fiber resin, a prepreg, or polyimide.

4. The substrate structure according to claim 1, wherein the second substrate and the third substrate respectively have an inorganic base, and a material of the inorganic base comprises glass, ceramic, or glass ceramic.

5. The substrate structure according to claim 1, wherein the electroless metal material comprises electroless copper plating, electroless gold plating, or electroless nickel plating.

6. The substrate structure according to claim 1, wherein the second substrate further comprises at least one first wiring pattern facing the first surface, the third substrate further comprises at least one second wiring pattern facing the second surface, and the electroless metal material further covers a peripheral surface of the at least one first wiring pattern and a peripheral surface of the at least one second wiring pattern.

7. The substrate structure according to claim 1, wherein the electroless metal material exposes a part of the first surface and a part of the second surface of the first substrate, a part of a third surface of the second substrate facing the first surface, and a part of a fourth surface of the third substrate facing the second surface.

8. The substrate structure according to claim 1, wherein the at least one first conductive via and the at least one second conductive via are located on a same axis.

9. The substrate structure according to claim 1, wherein the at least one first conductive via and the at least one third conductive via are located on a same axis.

10. The substrate structure according to claim 1, wherein respectively between the first nano-metal wires and the third nano-metal wires and between the second nano-metal wires and the fourth nano-metal wires, one of following conditions is satisfied:
(1) complete direct contact;
(2) partial direct contact; and
(3) no contact.

11. The substrate structure according to claim 1. wherein a length of each of the first nano-metal wires, a length of each of the second nano-metal wires. a length of each of the third nano-metal wires, and a length of each of the fourth nano-metal wires are between 1 um and 50 μm.
